(19) United States
(12) Patent Application Publication
(10) Pub. No.: US 2026/0107507 A1
(43) Pub. Date: Apr. 16, 2026

(54) DUAL BACKSIDE VIA LINERS

(71) Applicant: International Business Machines Corporation, Armonk, NY (US)

(72) Inventors: Xiaoming Yang, Clifton Park, NY (US); Tao Li, Slingerlands, NY (US); Jidong Huang, Rexford, NY (US); HUIMEI ZHOU, Albany, NY (US); Ravikumar Ramachandran, Pleasantville, NY (US)

(21) Appl. No.: 18/911,951

(22) Filed: Oct. 10, 2024

(51) Int. Cl. H01L 29/417; H01L 27/092; H01L 29/06; H01L 29/423; H01L 29/775; H01L 29/786

(52) U.S. Cl. CPC H10D 30/6729; H10D 30/43; H10D 30/6735; H10D 30/6757; H10D 62/121; H10D 84/856

(57) ABSTRACT

A semiconductor device is provided in which a frontside power via structure is in contact with a backside contact via structure that contains dual backside via liners present thereon. Notably, an inner backside via dielectric liner is located on a sidewall of the backside contact via structure, and an outer backside via dielectric liner is located on a sidewall of the inner backside via dielectric liner and on a topmost surface of the backside contact via structure.

### BACKGROUND

The present application relates to semiconductor technology, and more particularly to a semiconductor device including a frontside power via structure that is in contact with a backside contact via structure that includes dual backside via liners present thereon.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance).

### SUMMARY

A semiconductor device is provided in which a frontside power via structure is in contact with a backside contact via structure that contains dual backside via liners present thereon. Notably, an inner backside via dielectric liner is located on a sidewall of the backside contact via structure, and an outer backside via dielectric liner is located on a sidewall of the inner backside via dielectric liner and on a topmost surface of the backside contact via structure. The presence of the dual backside via liners provides good isolation to prevent shorts between electrical lines to a semiconductor substrate.

In one aspect of the present application, a semiconductor device is provided. In one embodiment of the present application, the semiconductor device includes a frontside power via structure located adjacent to a gate structure and a source/drain region of a transistor, the frontside power via structure including a power via pillar. The semiconductor device further includes a backside contact via structure in direct physical contact with a bottommost surface of the power via pillar, an inner backside via dielectric liner located on a sidewall of the backside contact via structure, and an outer backside via dielectric liner located on a sidewall of the inner backside via dielectric liner and on a topmost surface of the backside contact via structure.

In another embodiment of the present application, the semiconductor device includes a frontside power via structure located adjacent to a gate structure and a source/drain region of a transistor, the frontside power via structure including a power via pillar. The semiconductor device of this embodiment further includes a backside contact via structure in direct physical contact with a bottommost surface of the power via pillar and being electrically connected to the source/drain region of the transistor by a frontside source/drain contact structure, an inner backside via dielectric liner located on a sidewall of the backside contact via structure, and an outer backside via dielectric liner located on a sidewall of the inner backside via dielectric liner and a topmost surface of the backside contact via structure.

### BRIEF DESCRIPTION OF THE DRAWINGS

FIG. 1 is a top down view of a device layout that can be employed in the present application.

FIGS. 2A-2B are cross sectional views of an exemplary structure through cut A-A and cut B-B, respectively, that can be employed in accordance with an embodiment of the present application.

FIGS. 3A-3B are cross sectional views of the exemplary structure shown in FIGS. 2A and 2B, respectively, after removing a semiconductor base layer of the exemplary structure to reveal an etch stop layer of the exemplary structure.

FIGS. 4A-4B are cross sectional views of the exemplary structure shown in FIGS. 3A and 3B, respectively, after removing the etch stop layer to reveal a semiconductor device layer of the exemplary structure.

FIGS. 5A-5B are cross sectional views of the exemplary structure shown in FIGS. 4A and 4B, respectively, after backside via patterning.

FIGS. 6A-6B are cross sectional views of the exemplary structure shown in FIGS. 5A and 5B, respectively, after forming a first backside via dielectric layer and a second backside via dielectric layer in a backside via opening provided by the backside patterning.

FIGS. 7A-7B are cross sectional views of an alternative exemplary structure after forming a first backside via dielectric layer and a second backside via dielectric layer in a backside via opening provided by the backside patterning

FIGS. 8A-8B are cross sectional views of the exemplary structure shown in FIGS. 6A and 6B, respectively, after revealing a bottommost surface of a power via pillar.

FIGS. 9A-9B are cross sectional views of the exemplary structure shown in FIGS. 8A and 8B, respectively, after forming a backside contact via structure in a remaining volume of the backside via opening.

FIGS. 10A-10B are cross sectional views of the exemplary structure shown in FIGS. 9A and 9B, respectively, after forming a backside BEOL structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside BEOL structure. The backside BEOL structure can be a backside power distribution network that is capable of delivering power to the transistor through the backside of the semiconductor device.

Backside BEOL structure backside to frontside overly is a critical issue in a semiconductor device containing backside power delivery due to bonding that is used in forming the semiconductor device. Current backside contact via structure to frontside power via structure overlay is around 8 to 10 nm, with a worst case being around 20 nm. To ensure that the backside contact via structure is electrically connected to the frontside power via structure, the backside contact via structure needs to be wide enough, considering overlay and critical dimension variations. In the present application, a semiconductor device having a good electrically connection between the frontside power via structure and the backside contact via structure is provided. The present application also describes a method of forming such a semiconductor device.

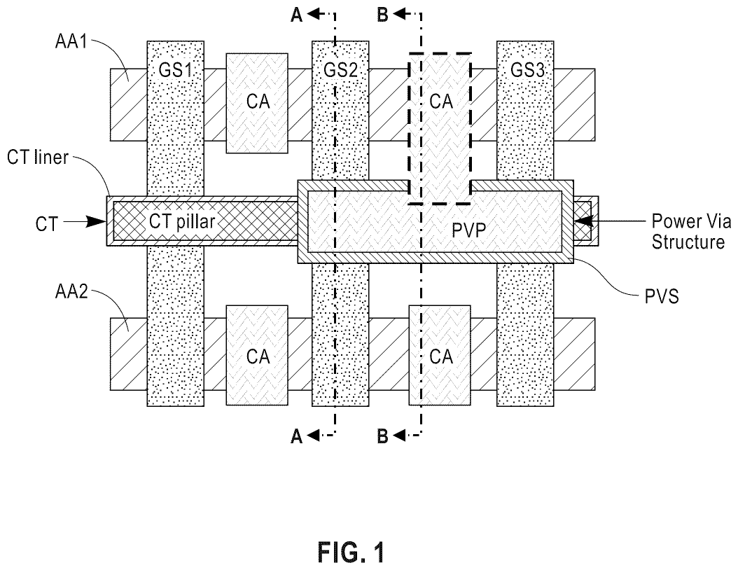

Referring first to FIG. 1, there is illustrated a top down view of a device layout that can be employed in the present application. The device layout illustrated in FIG. 1 includes two active device areas, notably, first active device area AA1 and second active device area AA2, that lie parallel to each other. AA1 and AA2 are separated by a non-active device area. A non-active device area is an area in which active semiconductor devices are not formed. The illustrated device layout shown in FIG. 1 also includes three gate structures, namely GS1, GS2 and GS3, that run parallel to each other and perpendicular to each active device area. The three gate structures are cut in the non-active device area and are separated from each other by a gate trench structure, CT. The gate cut structure includes a gate cut liner, CT liner, and a gate cut dielectric pillar, CT pillar, as illustrated in FIG. 1.

It is noted that the present application is not limited to two active device areas and three gate structures as is illustrated in FIG. 1. Frontside source/drain contact structures, CA, are also shown in FIG. 1. The device layout illustrated in FIG. 1 further includes a frontside power via structure including a power via spacer, PVS, and a power via pillar, PVP. As is shown, the frontside power via structure is located in the non-active device area and adjacent to the gate cut trench structure, CT. In the illustrated embodiment shown in FIG. 1, one of the frontside source/drain contact structure, CA, provides electrical connection between a source/drain region of one of the transistors and the power via pillar, PVP. Other embodiments are possible in which power via pillar, PVP, is not electrically connected to the source/drain region through a frontside source/drain contact structure.

The device layout illustrated in FIG. 1 further includes cut A-A and cut B-B. Cut A-A and cut B-B run in a same direction as shown in FIG. 1 and both cuts run in a length wise direction of each gate structure and pass through each of the first active device area, AA1, the non-active device area, and the second active device area, AA2. Note that both cuts pass through the frontside power via structure. Notably, cut A-A runs through a portion of the second gate structure, GS2, while cut B-B is present in a source/drain area that is located adjacent to the second gate structure, GS2 highlighted by cut A-A. A source/drain area is an area in which source/drain regions (or structures) will be present.

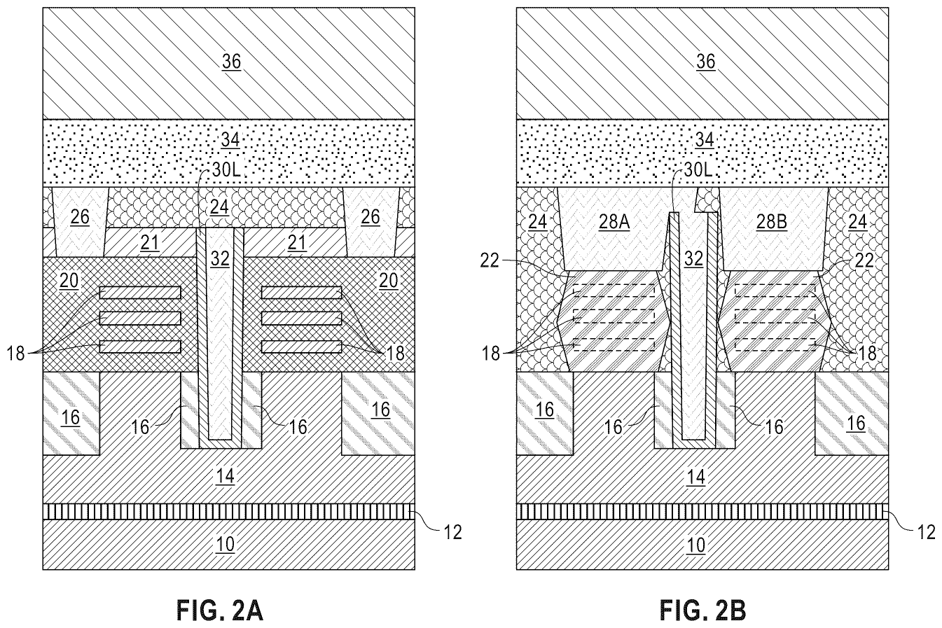

In the present application, each of FIGS. 2A, 3A, 4A, 5A, 6A, 7A, 8A, 9A and 10A is a cross sectional view of an exemplary structure through various processing stages along the cut A-A, while each of FIGS. 2B, 3B, 4B, 5B, 6B, 7B, 8B, 9B and 10B is a cross sectional view of the exemplary structure through various processing stages along the cut B-B.

Referring now to FIGS. 2A-2B, there are illustrated an exemplary structure through cut A-A and cut B-B, respectively, that can be employed in accordance with an embodiment of the present application. The exemplary structure shown in FIGS. 2A-2B includes a substrate that includes at least a semiconductor device layer 14. The substrate can also include a semiconductor base layer 10 and/or an etch stop layer 12. In the illustrated embodiment, the substrate includes semiconductor base layer 10, etch stop layer 12 and semiconductor device layer 14. The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

The exemplary structure shown in FIGS. 2A-2B can further include a shallow trench isolation structure 16. The shallow trench isolation structure 16 is located in an upper portion of the substrate (e.g., the semiconductor device layer 14). The shallow trench isolation structure 16 can include a trench dielectric liner and a trench dielectric material. The trench dielectric liner includes a trench dielectric liner material such as, for example, silicon nitride. The trench dielectric material is composed of any trench dielectric such as, for example, silicon dioxide. The trench dielectric liner is present along a sidewall and a bottom wall of the trench dielectric material. In some embodiments, the shallow trench isolation structure 16 can have a topmost surface that is substantially coplanar with a topmost surface of the substrate (e.g., the semiconductor device layer 14). In other embodiments, the shallow trench isolation structure 16 can have a topmost surface that is vertically offset (i.e., higher or lower) than a topmost surface of the substrate (e.g., the semiconductor device layer 14).

The exemplary structure shown in FIGS. 2A-2B further includes at least one transistor (two transistors are illustrated in FIGS. 2A-2B). In the illustrated embodiments, each transistor is a nanosheet transistor that includes a vertical stack of spaced apart semiconductor channel material nanosheets 18, a gate structure 20, and source/drain regions 22. An optional gate cap 21 can be located on top of the gate structure 20 of each transistor. Each semiconductor channel material nanosheet 18 is composed of a fourth semiconductor material. The fourth semiconductor material can be compositionally the same as, or compositionally different from, the second semiconductor material that provides the semiconductor device layer 14. In some embodiments, the fourth semiconductor material that provides each semiconductor channel material nanosheet 18 provides high channel mobility for NFET devices. In other embodiments, the fourth semiconductor material that provides each semiconductor channel material nanosheet 18 provides high channel mobility for PFET devices. In one example, each semiconductor channel material nanosheet 18 is composed of silicon. The number of semiconductor channel material nanosheets 18 present in each vertical stack of semiconductor channel material nanosheets can vary and it not limited to three as exemplified in FIG. 2A.

The gate structure 20 includes a gate dielectric material and a gate electrode, both of which are not separately shown, but intended to be within the region defined by the gate structure 20 illustrated in FIG. 2A. As is known to those skilled in the art, a gate dielectric material directly contacts a physically exposed surface(s) of the semiconductor channel region (e.g., the vertical stack of semiconductor channel material nanosheets 18), and a gate electrode is formed on the gate dielectric material. The gate dielectric material has a dielectric constant of 4.0 or greater. All dielectric constants mentioned herein are measured in a vacuum, unless stated to the contrary. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to, aluminum (Al), tungsten (W), or cobalt (Co).

When present, the gate cap 21 is composed of a dielectric hard mask material including, for example, silicon dioxide, silicon nitride and/or silicon nitride. The gate cap 21 is located on top of each gate structure 20.

Each source/drain region 22 is located on opposing sides of a given vertical stack of semiconductor channel material nanosheets 18. FIG. 2B illustrates one side of a given vertical stack of spaced apart semiconductor channel material nanosheets 18. Each source/drain region 22 extends outward from a sidewall of the semiconductor channel material nanosheets 18 of a given vertical stack of spaced apart semiconductor channel material nanosheets 18; in FIG. 2B the semiconductor channel material nanosheets 18 are illustrated as dotted lines to represent that those nanosheets are located behind the source/drain regions 22 illustrated in FIG. 2B. Each source/drain region 22 is composed of a fifth semiconductor material and a dopant. As used herein, a “source/drain” region can be a source region or a drain region depending on subsequent wiring and application of voltages during operation of the transistor. The fifth semiconductor material that provides the source/drain regions 22 can be compositionally the same as, or compositionally different from, the fourth semiconductor material that provides each semiconductor channel material nanosheet 18. The dopant that is present in the source/drain regions 22 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region 22 can have a dopant concentration of from 4×10²⁰ atoms/cm³ to 3×10²¹ atoms/cm³. As is shown in FIG. 2B, each source/drain region 22 contacts a surface of the semiconductor device layer 14 of the substrate.

The transistors illustrated in FIGS. 2A-2B can be formed utilizing any well-known nanosheet transistor device fabrication process in which a gate cut process is employed. The nanosheet transistor device fabrication process typically includes the use of a sacrificial gate structure which is used in defining a nanosheet stack of alternating sacrificial semiconductor nanosheets and semiconductor channel material nanosheets. After defining the nanosheet stack, the sacrificial gate structure is removed to reveal the underlying nanosheet stack and thereafter each sacrificial semiconductor material nanosheet of the nanosheet stack is removed and thereafter a gate structure is formed wrapping around each of the suspended semiconductor channel material nanosheets of the nanosheet stack. A gate cut process is performed after forming the gate structure.

The gate cut structure is not illustrated in the cross sectional view represented by cut A-A or cut B-B. The gate cut structure includes a gate cut liner and a gate cut dielectric pillar. The gate cut liner is composed of a first dielectric material, while the gate cut dielectric pillar is composed of a second dielectric material that is compositionally different as compared to the first dielectric material such that the gate cut liner and the gate cut dielectric pillar of the gate cut structure have different etch rates. The first dielectric material that provides the gate cut liner includes, for example, SiO₂, SIN, SiBCN, SiOCN or SiOC. The second dielectric material that provides the gate cut dielectric pillar includes, for example, SiN, SiOCN, SiBCN, or SiO₂. In one example, the first dielectric material that provides the gate cut liner is SiO₂, while the second dielectric material that provides the gate cut dielectric pillar is SiN. The gate cut liner is present on a sidewall and a bottom surface of the gate cut dielectric pillar.

Each source/drain region 22 is embedded in a frontside interlayer dielectric (ILD) multilayered structure 24 which includes at least two frontside ILD layers. Each frontside ILD layer is composed of an ILD material such, as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. Each ILD layer that provides the frontside ILD multilayered structure 24 can be formed by a deposition process such as, for example, chemical vapor deposition (CVD), plasma enhanced chemical vapor deposition (PECVD) or spin-on coating. A planarization process such as, for example, chemical mechanical planarization (CMP) can be performed after the deposition of each ILD layer that provides the frontside ILD multilayered structure 24.

Embedded in an upper portion of the frontside interlayer dielectric (ILD) multilayered structure 24 are various frontside contact structures including frontside gate contact structures 26 and frontside source/drain contact structures 28A, 28B. Collectively, the frontside ILD multilayered structure 24 and the frontside contact structure can be referred to as a middle-of-the-line (MOL) structure. Each frontside gate contact structure 26 contacts the gate electrode of the gate structure 20, while each frontside source/drain contact structure 28B contacts a surface of one of the source/drain regions 22 of the nanosheet transistor. Each frontside gate contact structure 26 electrically connects a gate structure 20 of one of the transistors to frontside BEOL structure 34. Each frontside source/drain contact structure 28B electrically connects a source/drain region 22 of one of the transistors to the frontside BEOL structure 34. Frontside source/drain contact structure 28A electrically connects a source/drain region 22 of one of the transistors to a power via pillar 32 of a frontside power via structure as well to frontside BEOL structure 34. Each of the frontside contact structures is composed of at least a contact conductor material such as, for example W, Cu, Al, Co, Ru, Mo, Os, Ir, Rh, or an alloy thereof. Each of frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as exemplified above. Each frontside contact structure is formed by forming a contact opening by lithography and etching, and then a materialization process including filling at least a contact conductor material, and then performing a planarization process is performed . . . .

The exemplary structure shown in FIGS. 2A-2B further includes a frontside power via structure including a power via liner 30L and the power via pillar 32. As shown, the power via liner 30L is present on a sidewall and a bottom surface of the power via pillar 32. The frontside power via structure has a topmost surface that is substantially coplanar with a topmost surface of gate cap 21 (when the same is present) and a bottommost surface that lands on a sub-surface of the semiconductor device layer 14. The term “sub-surface” denotes a surface of a material layer/structure that is located between a topmost surface and a bottom most surface of the same material layer/structure. In the present application, the frontside power via structure passes entirely through the frontside ILD multilayered structure 24, the optional gate cap 21 (if the same is present) and the shallow trench isolation structure 16, and partially through the semiconductor device layer 14. The frontside power via structure is located between adjacent gate structures 20 (See, for example, FIG. 2A) and adjacent source/drain regions 22 (See, for example, FIG. 2B).

The power via liner 30L is composed of a power via liner material. In some embodiments, the power via liner material that provides the power via liner 30L can be an adhesion metal material such as, for example, Ti, Ta, TIN, TiN or any combination thereof. In some embodiments, the power via liner material that provides the power via liner 30L can be composed of a silicide such as, for example, as TiSi, NiSi, NiPtSi or any combination thereof. In yet other embodiments, the power via liner material that provides the power via liner 30L includes a combination of an adhesion metal materiel and a silicide. The power via pillar 32 is composed of a contact conductor material such as, for example W, Cu, Al, Co, Ru, Mo, Os, Ir, Rh, or an alloy thereof.

The frontside power via structure including the power via liner 30L and the power via pillar 32 can be formed by a first forming a frontside power via structure opening in the exemplary structure (the power via opening is formed in gate cut structure described above), and then performing a metallization process which includes filling the frontside power via structure opening with a power via liner material and then a contact conductor material, and thereafter a planarization process is performed.

The exemplary structure shown in FIGS. 2A-2B further includes a frontside BEOL structure 34 and a carrier wafer 36. The frontside BEOL structure 34 is formed on top of the MOL structure (and is thus above the gate structure 20 and the frontside power via structure) and is in electrical contact with the frontside contact structures, e.g., the frontside gate contact structures 26 and frontside source/drain contact structures 28A, 28B. The frontside BEOL structure 34 is composed of an interconnect dielectric region having frontside metal wiring embedded therein; the frontside metal wiring present in the frontside BEOL structure 34 is typically signal wires. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. The frontside BEOL structure 34 can be formed utilizing any well-known BEOL process including a damascene process or a subtractive metal etch process. It is noted that the frontside BEOL structure 34 is electrically connected to each of the transistors through the frontside contact structures described above.

Carrier wafer 36 can include a semiconductor material as exemplified above. Carrier wafer 36 is bonded to the frontside BEOL structure 34 by a bonding dielectric layer (not illustrated in the drawings of the present application). Illustrative examples of dielectric materials that are used as the bonding dielectric layer include, but are not limited to, tetraethyl orthosilicate (TEOS), SiO₂ silicon carbon nitride (SiCN) and/or carbon-doped silicon oxide (SiCOH). The carrier wafer 36 is formed on the frontside BEOL structure 34 by a bonding process. The bonding process includes any bonding process that is well known to those skilled in the art.

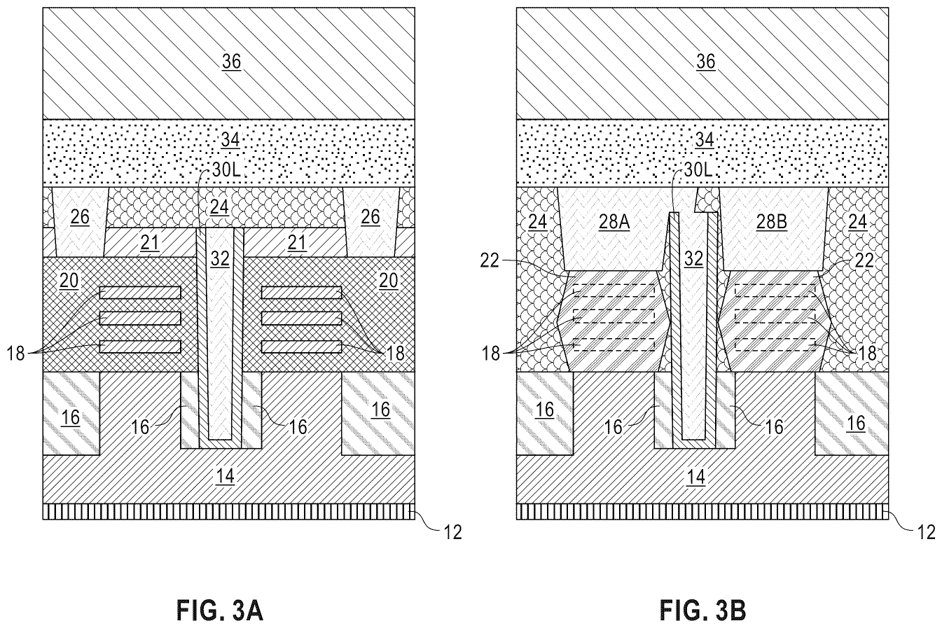

Referring now to FIGS. 3A-3B, there are illustrated the exemplary structure shown in FIGS. 2A and 2B, respectively, after removing the semiconductor base layer 10 of the exemplary structure to reveal the etch stop layer 12 of the exemplary structure. This step can be omitted when no semiconductor base layer 10 is present. Prior to removing the semiconductor base layer 10, the exemplary structure illustrated in FIGS. 2A-2B is flipped 180° to physically expose a backside of the structure. For clarity, the flipping step is not shown in the drawings. Flipping can be performed by hand or by utilizing a mechanical means such as, for example, a robot arm. After flipping, the semiconductor base layer 10 is physically exposed and the physically exposed semiconductor base layer 10 is removed utilizing a material removal process that is selective in removing the semiconductor material that provides the semiconductor base layer 10. The removal of the semiconductor base layer 10 reveals the etch stop layer 12 of the substrate.

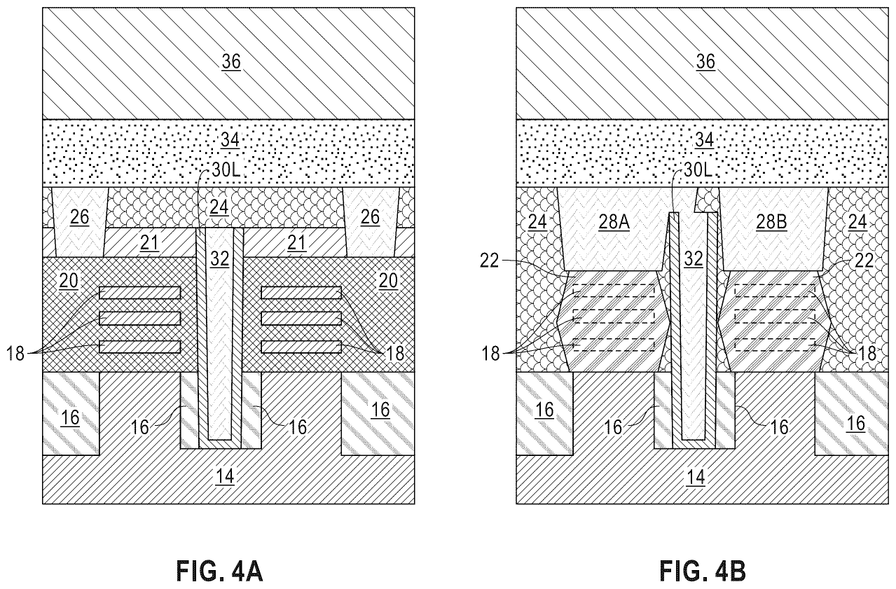

Referring now to FIGS. 4A-4B, there are illustrated the exemplary structure shown in FIGS. 3A and 3B, respectively, after removing the etch stop layer 12 to reveal the semiconductor device layer 14 of the exemplary structure. The etch stop layer 12 can be removed utilizing a material removal process that is selective in removing the material that provides the etch stop layer 12. The removal of the etch stop layer 12 physically exposes the semiconductor device layer 14. It is noted that the removal of the etch stop layer 12 can be omitted when such a layer is not present. In some embodiments and following the removal of the etch stop layer 12, the semiconductor device layer 14 can be thinned utilizing an etching process or a planarization process.

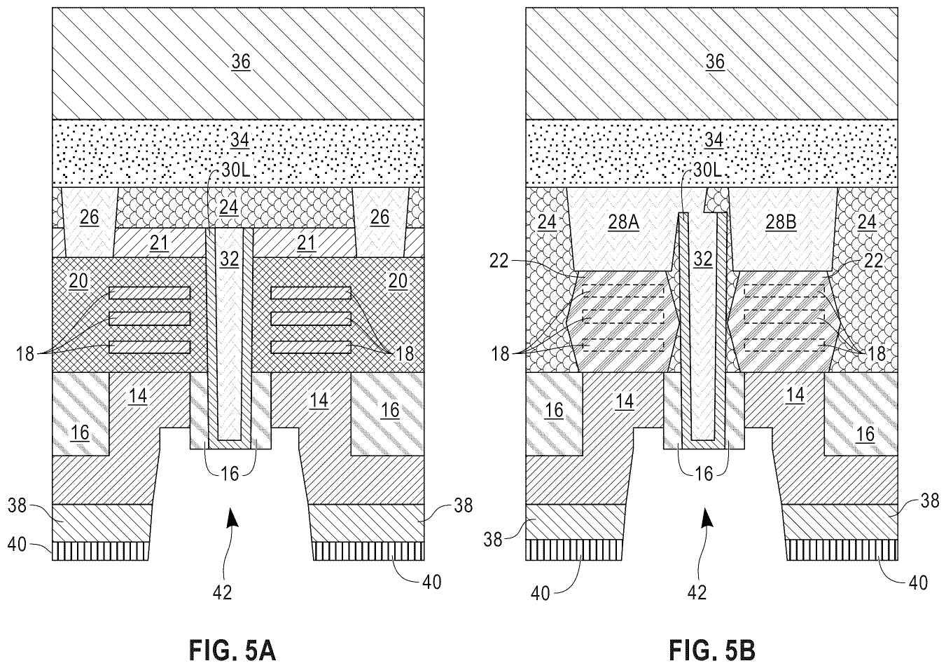

Referring now to FIGS. 5A-5B, there are illustrated the exemplary structure shown in FIGS. 4A and 4B, respectively, after backside via patterning. Prior to backside via patterning, a backside ILD layer 38 is formed on the physically exposed surface of the semiconductor device layer 14. The backside ILD layer 38 is composed of an ILD material including those mentioned above. The backside ILD layer 38 can be formed by deposition (e.g., CVD, PECVD, or spin-on coating), followed by a planarization process.

After forming the backside ILD layer 38, a hard mask layer 40 is formed on the backside ILD layer 38. The hard mask layer 40 is composed of one or more dielectric hard mask materials such as, for example, silicon dioxide, silicon nitride and/or silicon nitride. The dielectric hard mask material used in providing the hard mask layer 40 is compositionally different from the ILD material used in providing the backside ILD layer. The hard mask layer 40 can be formed utilizing a deposition process such as, for example, CVD, PECVD, or physical vapor deposition (PVD).

Backside patterning is now performed. Backside patterning includes a lithographic patterning process to provide an opening in the hard mask layer 40. The opening that is formed in the hard mask layer 40 coincides with the area in which a backside via opening 42 will be subsequently formed. Lithographic patterning includes the use of a patterned photoresist which can be removed after forming the opening in the hard mask layer 40. One or more etching processes are then performed to transfer the opening in the hard mask layer 40 into the backside ILD layer 38 and then the semiconductor device layer 14. Etching processes can include dry etching (i.e., reactive ion etching (RIE), ion beam etching (IBE) or plasma etching), and/or wet etching (wet etching includes the use of a chemical etchant that is selective in removing one material layer compared to another material layer).

In the present application, the backside via opening 42 has a critical dimension (i.e., width) that is greater than a critical dimension (i.e., width) of the frontside power via structure such that the backside via opening 42 is located adjacent to a sidewall of the frontside power via structure as is illustrated in FIGS. 5A-5B. The backside via opening 42 physically exposes a bottom surface of the power via liner 30L, as well as surfaces (sidewall and bottom surface) of the shallow trench isolation structure 16 and surfaces of the semiconductor device layer 14.

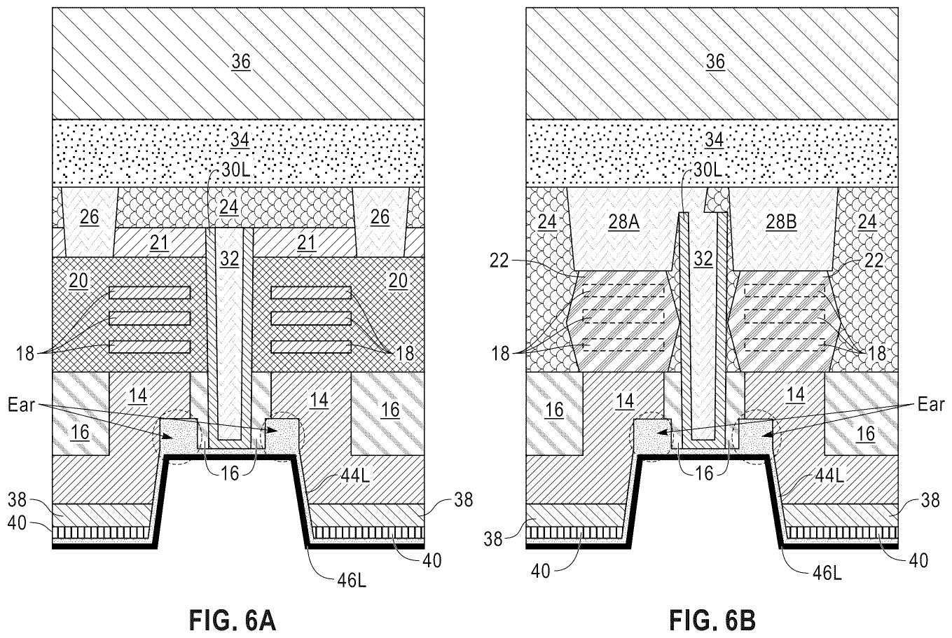

Referring now to FIGS. 6A-6B, there are illustrated the exemplary structure shown in FIGS. 5A and 5B, respectively, after forming a first backside via dielectric layer 44L and a second backside via dielectric layer 46L in the backside via opening 42 provided by the backside patterning. The first backside via dielectric layer 44L is composed of a first dielectric liner material, while the second backside via dielectric layer 46L is composed of a second dielectric liner material which is compositionally different from the first backside dielectric liner material. In one example, the first backside dielectric liner material is silicon dioxide, while the second backside dielectric liner material is silicon nitride. It is noted that since the first backside via dielectric layer 44L and the second backside via dielectric layer 46L are composed of compositionally different dielectric liner materials, an etch selectivity can be obtained using the same. Notably, the second backside via dielectric layer 46L can be etched selective to the first backside via dielectric layer 44L and the first backside via dielectric layer 44L serves an etch stop layer for such an etch.

The exemplary structure shown in FIGS. 6A-6B can be formed by first depositing the first dielectric liner material that provides the first backside via dielectric layer 44L, and then second depositing the second dielectric liner material that provides the second backside via dielectric layer 46L. The first depositing and the second depositing can include a same, or different, deposition process such as, for example, CVD, PECVD or atomic layer deposition (ALD). In some embodiments, ALD is used in forming both the a first backside via dielectric layer 44L and the second backside via dielectric layer 46L. In the embodiment illustrated in FIGS. 6A-6B, first backside via dielectric layer 44L has an “ear” portion located on in a trench region present on each side of the frontside power via structure.

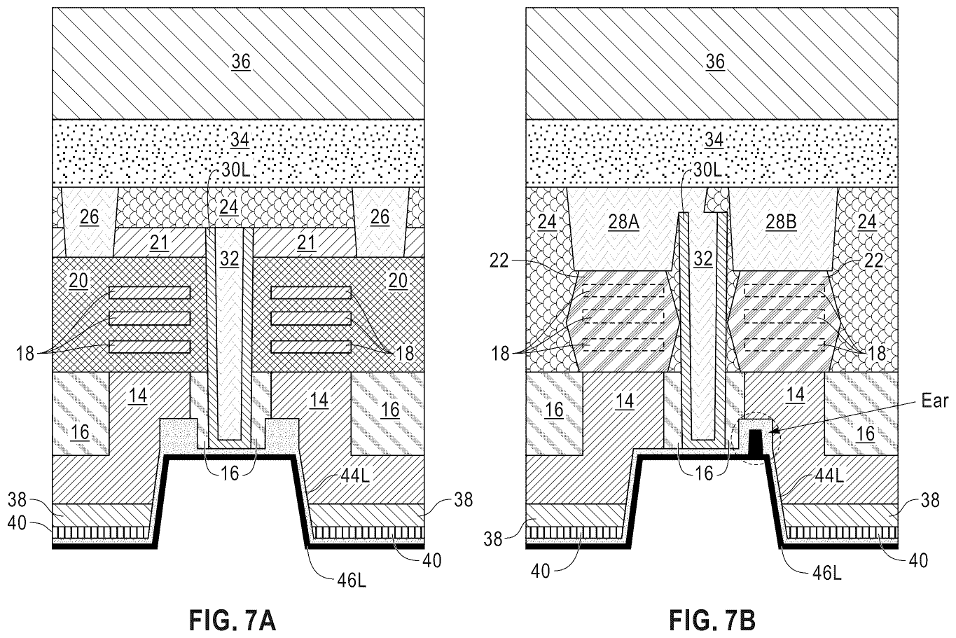

Referring now to FIGS. 7A-7B, there are illustrated an alternative exemplary structure through cut A-A and cut B-B, shown in FIG. 1, respectively, that can be formed after forming a first backside via dielectric layer 44L and a second backside via dielectric layer 46L in the backside via opening 42 provided by the backside patterning. The exemplary structure illustrated in FIGS. 7A-7B represents an embodiment in which an overlayer shift to one side of the frontside power via structure occurs. In the embodiment illustrated in FIG. 7A, the first backside via dielectric layer 44L has an “ear” portion located in a trench region that is located on each side of the frontside power via structure, while in FIG. 7B, the first backside via dielectric layer 44L and the second backside via dielectric layer 46L both have an “ear” portion located in a trench region that is located on one side of the frontside power via structure. The present application works for the embodiment shown in FIGS. 6A-6B as well as the embodiment shown in FIGS. 7A-7B.

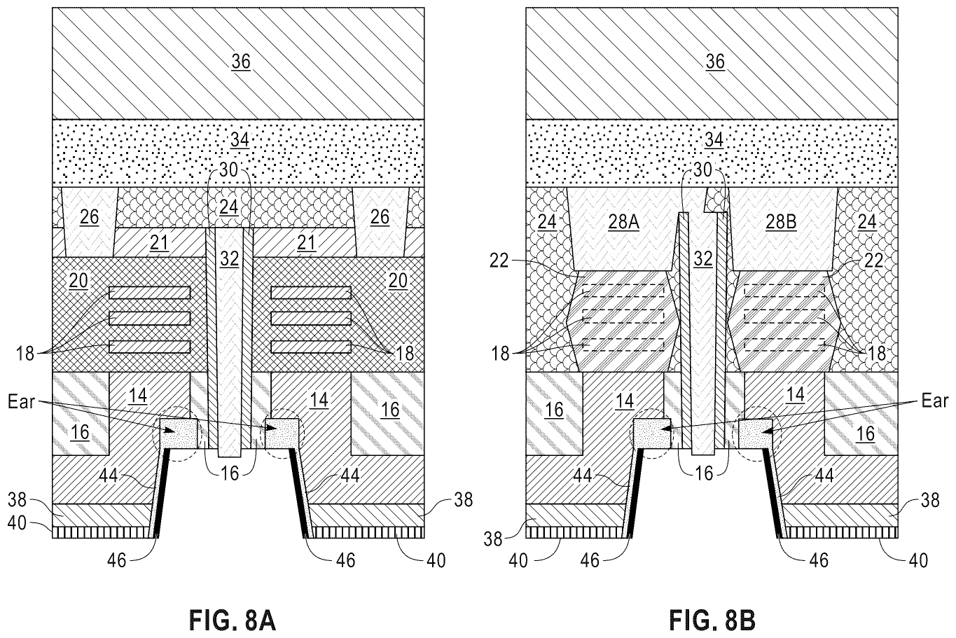

Referring now to FIGS. 8A-8B, there are illustrated the exemplary structure shown in FIGS. 6A and 6B, respectively, after revealing a bottommost surface of the power via pillar 32. Note that the exemplary structure shown in FIGS. 7A and 7B can be used instead of the exemplary structure shown in FIGS. 6A and 6B. The revealing includes an etch back process in which the second backside via dielectric layer 46L is etched selective to the first backside via dielectric layer 44L. The etch back process removes portions of both the second backside via dielectric layer 46L and the first backside via dielectric layer 44L that are located on the horizontal surface of the hard mask layer 40 and along the bottommost surface of the power via pillar 32, while leaving a portion of the second backside via dielectric layer 46L and a portion of the first backside via dielectric layer 44L along the sidewall of the backside via opening 42. Note that this etch can also remove a bottommost surface of the power via liner 30L. The portion of the first backside via dielectric layer 44L that remains in the backside via opening 42 provides an outer backside via dielectric liner 44 and the portion of the second backside via dielectric layer 46L that remains in the backside via opening 42 provides an inner backside via dielectric liner 46; the inner and outer designation is relative to the backside contact via structure 48 that is to be subsequently formed. Each remaining portion of the power via liner 30L is now referred to a power via spacer 30; the power via spacer 30 is present along the sidewall of the power via pillar 32 as is shown in FIGS. 8A-8B. In some embodiments and after performing the etch back, another etch such as RIE can be used to remove the bottommost surface of the power via liner 30L. In any event, the power via power is not reveled as is shown in FIGS. 8A-8B.

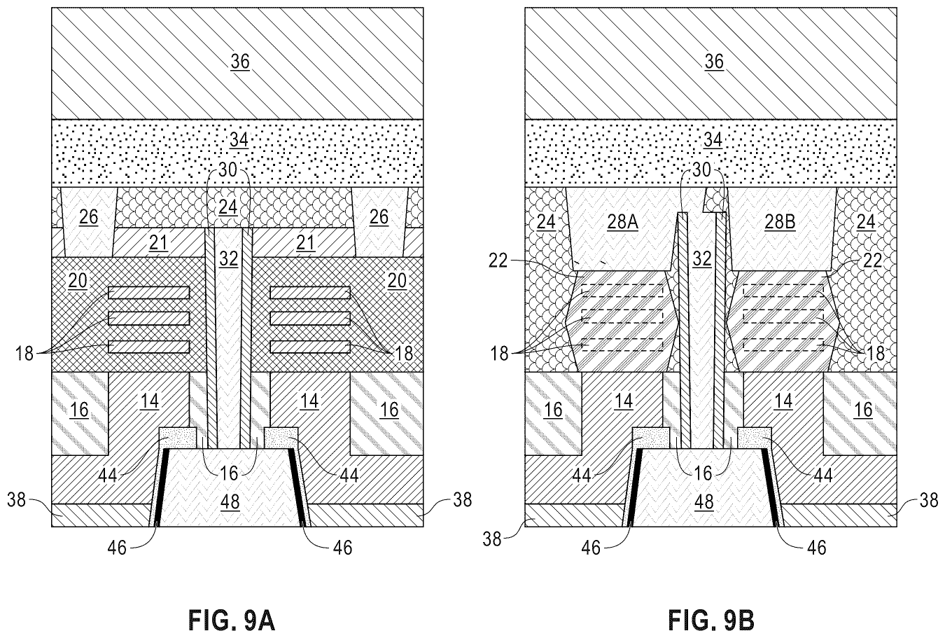

Referring now to FIGS. 9A-9B, there are illustrated the exemplary structure shown in FIGS. 8A and 8B, respectively, after forming a backside contact via structure 48 in a remaining volume of the backside via opening 42. The backside contact via structure 48 is composed of at least a contact conductor material as mentioned above for the frontside contact structures. The backside contact via structure 48 can also include, in addition to the contact conductor material, one or more contact liners (not shown). The one or more contact liners that can be used in providing the backside contact via structure 48 include one of the contact liners mentioned above for the frontside contact structures. The backside contact via structure 48 can be formed by a metallization process as mentioned above. Note that the metallization process includes a planarization process which removes the hard mask layer 40 from the exemplary structure and reveals a surface of the backside ILD layer 38.

As is shown, the backside contact via structure 48 has a shape of a trapezoid in which the critical dimension (i.e., width) along an upper portion of the backside contact via structure 48 is larger than a critical dimension along a bottom portion of the backside contact via structure 48. The backside contact via structure 48 has a sidewall in which the inner backside via dielectric liner 46 is present on. The outer backside via dielectric liner 44 is located on the inner backside via dielectric liner 46. The outer backside via dielectric liner 44 has a surface that is located on a topmost surface of the backside contact via structure 48. In the present application, a sidewall of the outer backside via dielectric liner 44 that is located on the topmost surface of the backside contact via structure 48 is in contact with a sidewall of the shallow trench isolation structure 16 (that encases the frontside power via structure).

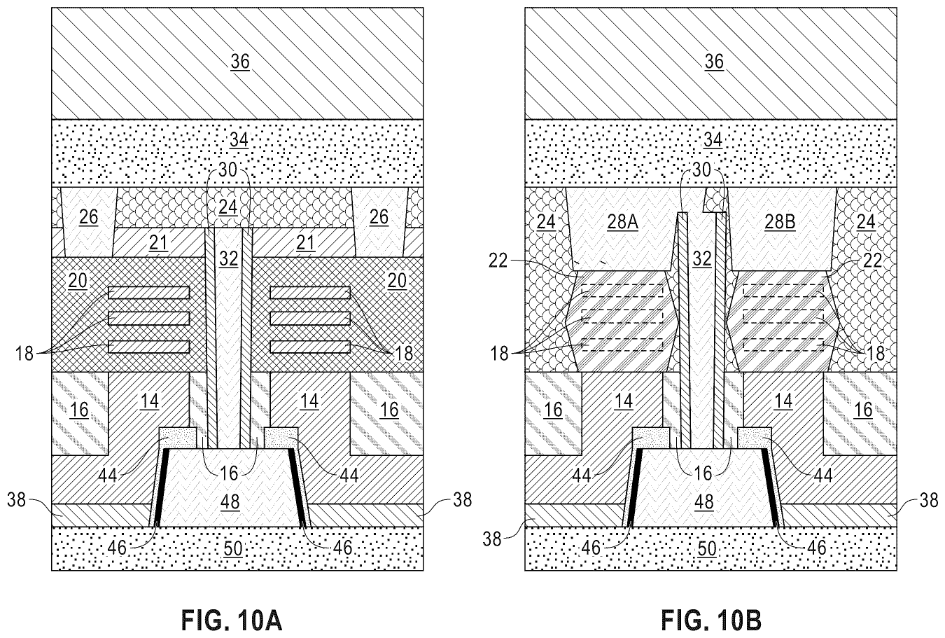

The backside contact via structure 48 provides electrical connection of the power via pillar 32 to backside BEOL structure 50 (See, for example, the exemplary structure shown in FIGS. 10A-10B). In the present application, the backside contact via structure 48 is located entirely beneath the bottommost surface of both the power via spacer 30 and the power via pillar 32 of the frontside power via structure.

Referring now to FIGS. 10A-10B, there are illustrated the exemplary structure shown in FIGS. 9A and 9B, respectively, after forming backside BEOL structure 50. The backside BEOL structure 50 (which can delivery power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 50 can be formed utilizing any well-known BEOL process including a damascene process or a subtractive metal etch process. As alluded to above, the backside BEOL structure 50 is electrically connected to the power via pillar 32 of the frontside power via structure by the backside contact via structure.

FIGS. 10A-10B illustrate a semiconductor device that includes frontside power via structure located adjacent to gate structure 20 and a source/drain region 22 of a transistor, the frontside power via structure including power via pillar 32. The semiconductor device further includes backside contact via structure 48 in direct physical contact with a bottommost surface of the power via pillar 32, inner backside via dielectric liner 46 located on a sidewall of the backside contact via structure 48, and outer backside via dielectric liner 46 located on a sidewall of the inner backside via dielectric liner 46 and a topmost surface of the backside contact via structure 48.

FIGS. 10A-10B also illustrate a semiconductor device that includes frontside power via structure located adjacent to gate structure 20 and a source/drain region 22 of a transistor, the frontside power via structure including power via pillar 32. The semiconductor device of this embodiment further includes backside contact via structure 48 in direct physical contact with a bottommost surface of the power via pillar 32 and being electrically connected to the source/drain region 22 of the transistor by frontside source/drain contact structure 28A, an inner backside via dielectric liner 46 located on a sidewall of the backside contact via structure 48, and an outer backside via dielectric liner 44 located on a sidewall of the inner backside via dielectric liner 46 and on a topmost surface of the backside contact via structure 48.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a frontside power via structure located adjacent to a gate structure and a source/drain region of a transistor, the frontside power via structure comprising a power via pillar;
a backside contact via structure in direct physical contact with a bottommost surface of the power via pillar; and
an inner backside via dielectric liner located on a sidewall of the backside contact via structure; and
an outer backside via dielectric liner located on a sidewall of the inner backside via dielectric liner and on a topmost surface of the backside contact via structure.

2. The semiconductor device of claim 1, further comprising a frontside source/drain contact structure electrically connecting the power via pillar to the source/drain region of the transistor.

3. The semiconductor device of claim 1, further comprising a frontside back-end-of-the-line (BEOL) structure located above the gate structure and the frontside power via structure.

4. The semiconductor device of claim 3, wherein the frontside BEOL structure is electrically connected to a gate electrode of the gate structure by a frontside gate contact structure.

5. The semiconductor device of claim 1, wherein the backside contact via structure further comprises a power via spacer present along a sidewall of the power via pillar.

6. The semiconductor device of claim 1, wherein the backside contact via structure passes entirely through a shallow trench isolation structure that is located in a semiconductor device layer that is present beneath the transistor.

7. The semiconductor device of claim 6, wherein the outer backside via dielectric liner that is located on the topmost surface of the backside contact via structure has a sidewall contacting the shallow trench isolation structure.

8. The semiconductor device of claim 1, wherein the backside contact via structure has a trapezoid shape having an upper portion with a first critical dimension, and a lower portion having a second critical dimension, wherein the second critical dimension is less than the first critical dimension.

9. The semiconductor device of claim 1, wherein backside contact via structure is located entirely beneath a bottommost surface of the power via pillar.

10. The semiconductor device of claim 1, further comprising a backside BEOL located beneath, and in contact with, the backside contact via structure.

11. The semiconductor device of claim 1, further comprising a gate cap located on the gate structure, wherein the frontside power via structure passes entirely through the gate cap.

12. The semiconductor device of claim 1, wherein the inner backside via dielectric liner is composed of a compositionally different dielectric material than the outer backside via dielectric liner.

13. The semiconductor device of claim 1, wherein the frontside power via structure is located adjacent to a gate cut structure.

14. The semiconductor device of claim 1, wherein the transistor is a nanosheet transistor.

15. A semiconductor device comprising:
a frontside power via structure located adjacent to a gate structure and a source/drain region of a transistor, the frontside power via structure comprising a power via pillar;
a backside contact via structure in direct physical contact with a bottommost surface of the power via pillar and being electrically connected to the source/drain region of the transistor by a frontside source/drain contact structure;
an inner backside via dielectric liner located on a sidewall of the backside contact via structure; and
an outer backside via dielectric liner located on a sidewall of the inner backside via dielectric liner and on a topmost surface of the backside contact via structure.

16. The semiconductor device of claim 15, further comprising a frontside BEOL structure located above the gate structure and the frontside power via structure.

17. The semiconductor device of claim 16, wherein the frontside BEOL structure is electrically connected to a gate electrode of the gate structure by a frontside gate contact structure, and to the source/drain region by the frontside source/drain contact structure.

18. The semiconductor device of claim 15, wherein the backside contact via structure passes entirely through a shallow trench isolation structure that is located in a semiconductor device layer that is present beneath the transistor.

19. The semiconductor device of claim 18, wherein the outer backside via dielectric liner that is located on the topmost surface of the backside contact via structure has a sidewall contacting the shallow trench isolation structure.

20. The semiconductor device of claim 15, further comprising a backside BEOL located beneath, and in contact with, the backside contact via structure.
